(19) United States
(12) Patent Application Publication
(10) Pub. No.: US 2014/0170053 A1
(43) Pub. Date: Jun. 19, 2014

(54) LOW FRICTION COATING LAYER, LOW FRICTION COATING METHOD AND LOW FRICTION COATING APPARATUS

(71) Applicant: HYUNDAI MOTOR COMPANY, Seoul (KR)

(72) Inventors: In Woong Lyo, Suwon (KR); Woong Pyo Hong, Yongin (KR); Hyuk Kang, Suwon (KR); Kwang Hoon Choi, Anyang (KR)

(73) Assignee: HYUNDAI MOTOR COMPANY, Seoul (KR)

(21) Appl. No.: 13/829,847

(22) Filed: Mar. 14, 2013

(30) Foreign Application Priority Data
Dec. 17, 2012 (KR) 10-2012-0147920

(51) Int. Cl. C23C 16/34; C09D 1/00; C23C 16/52

(52) U.S. Cl. CPC C23C 16/34; C23C 16/52; C09D 1/00
USPC 423/411; 427/576; 118/723 R

(57) ABSTRACT

Disclosed herein is a low friction coating layer wherein the uniform concentration of a low friction metal in the coating layer is increased by increasing a turning-on power of a low friction metal source to be higher than a turning-off power thereof, decreasing a turning-on power of a Ti source to be lower than a turning-off power thereof. Alternatively the concentration is increased by increasing a flow rate or temperature of a nitrogen atmosphere gas upon introduction to be higher than upon termination of the introduction thereof.

### BACKGROUND OF THE INVENTION

1. Field of the Invention

The present invention relates to a low friction coating layer, a low friction coating method, and a low friction coating apparatus, wherein process conditions (e.g., sputter power and arc power) are adjusted to form a substantially uniform low friction element composition at different depths of the layer, thus maintaining low friction characteristics during extended use of the coating layer.

2. Description of the Related Art

A novel titanium nitride (TiN) coating, having higher heat resistance of diamond-like carbon (DLC) than the coatings currently available as a coating for engine driving parts. In addition, although the coating has increased heat resistance and wear resistance, the coating has decreased low friction characteristics compared to currently available coatings, and thus the use thereof in a variety of driving parts is limited.

Therefore, a complex coating layer using a soft metal such as silver (Ag) or copper (Cu) may be formed to obtain desired low friction characteristics. However, when the amount of the soft metal (e.g., Ag, Cu) increases to maximize low friction characteristics, the soft metal may diffuse to the surface of the coating layer during the coating process, thereby varying the amount of Ag at the core and the surface of the coating layer. The use of a part having such a coating layer may result in wear, undesirably deteriorating low friction characteristics.

One known method, discloses a method of forming a thin film for use in electronic and electrical devices using sputtering. The thin film may protect a substrate or a lower layer or structure formed on the substrate from damage due to plasma and may have increased electrical/material properties. The target material may include conductive, semiconductive, resistive materials, etc., or examples thereof may include TCO (Transparent Conductive Oxide) such as ITO (Indium Tin Oxide). A deposition process includes forming a unit electronic material film or a unit electrode layer via sputtering and surface treating the unit electronic material film or the electrode layer using neutral particle beams obtained from non-reactive elements.”

The foregoing is intended merely to aid in the understanding of the background of the present invention, and is not intended to mean that the present invention falls within the purview of the related art that is already known to those skilled in the art.

### SUMMARY

Accordingly, the present invention provides a low friction coating layer, a low friction coating method, and a low friction coating apparatus, wherein process conditions (e.g., sputter power and arc power) may be adjusted to form a substantially uniform low friction element composition at different depths of the coating layer, thus maintaining low friction characteristics during extended use of the coating layer.

The present invention provides a low friction coating method using a plasma coating process, including increasing a turning-on power of a low friction metal source to be higher than a turning-off power thereof, decreasing a turning-on power of a titanium (Ti) source to be lower than a turning-off power thereof, or increasing a flow rate or temperature of a nitrogen atmosphere gas upon introduction to be higher than upon termination of the introduction thereof, to increase a substantially uniform concentration of a low friction metal in a coating layer.

The low friction metal may be silver (Ag) or copper (Cu), and the coating layer may be titanium silver nitride (TiAgN) or titanium copper nitride (TiCuN). The turning-on power of the low friction metal source may be about 5˜10% higher than the turning-off power thereof. The turning-on power of the Ti source may be about 3˜7% lower than the turning-off power thereof. The flow rate of the nitrogen atmosphere gas upon introduction may be about 20˜50% higher than upon termination of the introduction thereof. The temperature of the nitrogen atmosphere gas upon introduction may be about 15˜20% higher than upon termination of the introduction thereof.

In addition, the present invention provides a low friction coating layer, formed via a plasma coating process using a low friction metal source, a Ti source and a nitrogen gas, wherein the substantially uniform concentration of a low friction metal in the coating layer is increased by increasing a turning-on power of the low friction metal source to be higher than a turning-off power thereof, decreasing a turning-on power of the Ti source to be lower than a turning-off power thereof, or increasing a flow rate or temperature of a nitrogen atmosphere gas upon introduction to be higher than upon termination of the introduction thereof.

In addition, the present invention provides a low friction coating apparatus using a plasma coating process, including a jig having a substrate; a feeder configured to introduce a nitrogen gas as an atmosphere gas; a Ti source and a low friction metal source; and a controller configured to increase a turning-on power of the low friction metal source to be higher than a turning-off power thereof during coat, to decrease a turning-on power of the Ti source to be lower than turning-off power thereof, or to increase the flow rate or temperature of the nitrogen atmosphere gas upon introduction to be higher than upon termination of the introduction thereof.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplary view illustrating a low friction coating apparatus according to an exemplary embodiment of the present invention;

FIGS. 2 to 5 are exemplary views illustrating concentration of the composition of a low friction coating layer; and

FIG. 6 is an exemplary graph illustrating the effects of the low friction coating layer according to an exemplary embodiment of the present invention.

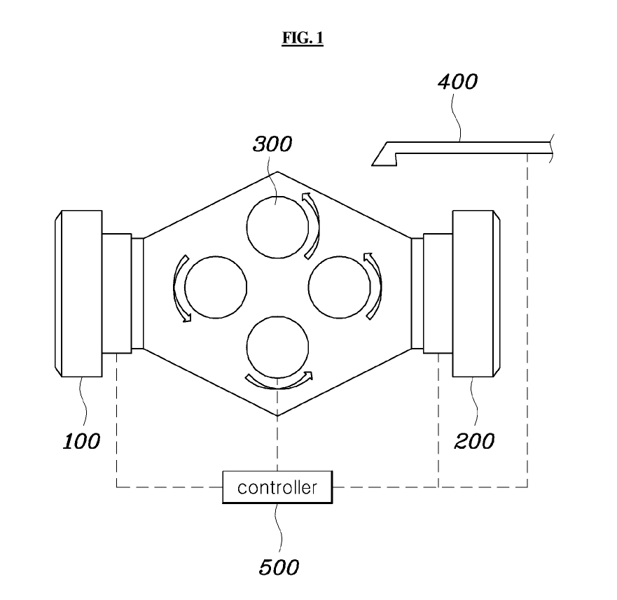

### DETAILED DESCRIPTION

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

Hereinafter, a detailed description will be given of a low friction coating layer, a low friction coating method, and a low friction coating apparatus according to exemplary embodiments of the present invention with reference to the accompanying drawings.

According to the present invention, a low friction coating layer may exhibit both heat resistance of titanium nitride (TiN) and low friction characteristics of a low friction metal, and may be manufactured using a plasma coating process.

Specifically, a low friction coating method according to the present invention may increase the substantially uniform concentration of the low friction metal in the coating layer by increasing a turning-on power of a low friction metal source to be higher than a turning-off power thereof, decreasing a turning-on power of a titanium (Ti) source to be lower than a turning-off power thereof, or increasing the flow rate or temperature of a nitrogen atmosphere gas upon introduction to be higher than upon termination of the introduction thereof.

When a low friction metal is subjected to plasma coating, low friction atoms may move to the surface of the coating layer at the temperature at which the coating layer is formed during the process. Thus, the low friction metal should be uniformly maintained at different depths of the coating layer. Thus, heating, cleaning, buffering, etc., may be performed prior to the above procedures. Buffering may be performed to form a Ti buffer using an ion source to enhance adhesion of a titanium silver nitride (TiAgN) which is a final functional coating layer, wherein the TiAgN layer may be implanted into a substrate of a test sample by increasing bias voltage of the substrate.

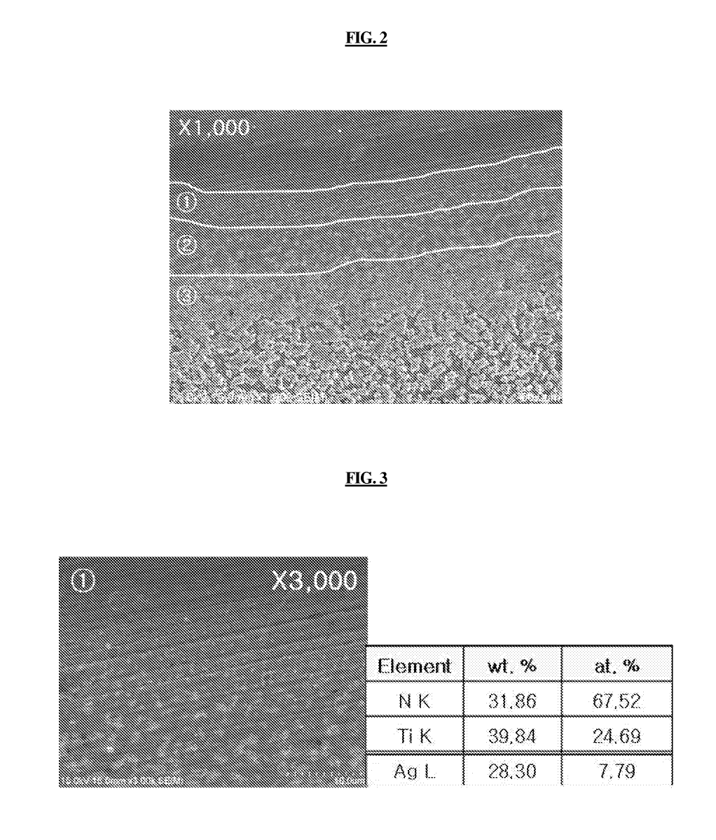

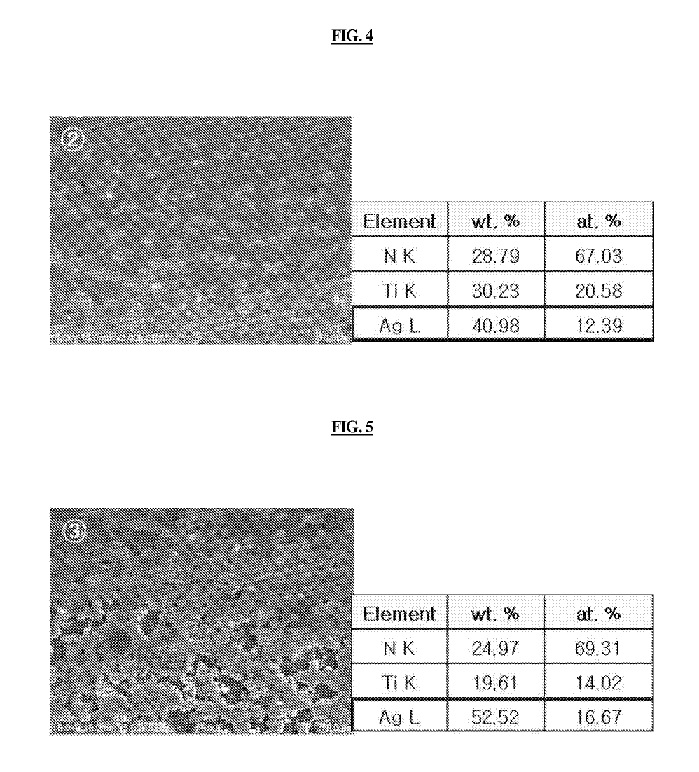

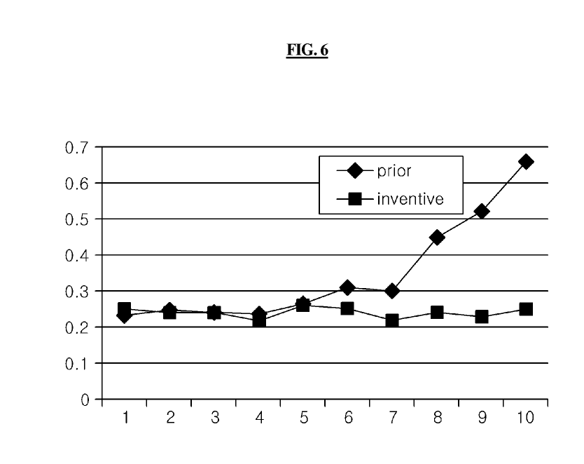

FIGS. 2 to 5 illustrate concentration of the composition of the low friction coating layer, and FIG. 2 illustrates the total structure of a conventional low friction coating layer in which the upward direction in the drawing corresponds to the inward direction of the coating layer.

As is illustrated in FIGS. 3, 4 and 5, the amount of silver (Ag), that is, a low friction metal, may increase toward the surface of the coating layer. The increase indicates that low friction characteristics of the surface may deteriorate upon extended use. Accordingly, the low friction metal should be uniformly maintained at different depths of the coating layer.

Moreover, the above process may be performed by 1) increasing the turning-on power of a low friction metal source to be higher than the turning-off power thereof, 2) decreasing the turning-on power of a Ti source to be lower than the turning-off power thereof, 3) increasing the flow rate or temperature of a nitrogen atmosphere gas upon introduction to be higher than upon termination of the introduction thereof, or 4) combinations of a combination of the above processes.

When the process is performed, the turning-on power of a sputter source (e.g., low friction metal) may increase to increase the amount of the low friction metal, and the turning-off power thereof may decrease to decrease the amount of the low friction metal, wherein the low friction metal appears on the surface of the coating layer. Thus, the coating layer in which the low friction metal is substantially uniformly distributed at different heights of the coating layer may be formed.

On the other hand, the turning-on power of an arc source (e.g., Ti source) may decrease to decrease the amount of Ti and thus the amount of the low friction metal may increase. The turning-off power of the arc source may increase to increase the amount of Ti and thus the amount of silver (Ag) may decrease, to thereby form the coating layer in which the low friction metal is substantially uniformly distributed at different heights of the coating layer.

Additionally, the flow rate and temperature of the nitrogen gas upon introduction may increase, thus improving low friction characteristics, and may decrease upon termination of the introduction thereof, thus decreasing low friction characteristics and increasing surface hardness, to form the coating layer in which the low friction metal is substantially uniformly distributed at different heights of the coating layer. The low friction metal may be Ag or copper (Cu), and thus the coating layer may be titanium silver nitride (TiAgN) or titanium copper nitride (TiCuN).

The turning-on power of the low friction metal source may be about 5˜10% higher than the turning-off power thereof. When this power difference is less than about 5%, changes in the amount may become insignificant. In contrast, when the power difference exceeds about 10%, the amount of the low friction metal of the core of the layer may increase.

In addition, the turning-on power of the Ti source may be about 3˜7% lower than the turning-off power thereof. When this power difference is less than about 3%, changes in the amount may become insignificant. In contrast, when the power difference exceeds about 7%, the amount of the low friction metal of the core of the layer may increase.

Furthermore, upon introduction of the nitrogen atmosphere gas, the flow rate may be about 20˜50% higher and the temperature may be about 15˜20% higher, compared to the termination of the introduction thereof. These numerical limitations are employed for the same reason as above.

Moreover, a low friction coating layer according to the present invention may be formed using a plasma coating process using a low friction metal source, a Ti source, and a nitrogen gas, and the substantially uniform concentration of the low friction metal in the coating layer may increase by increasing the turning-on power of the low friction metal source to be higher than the turning-off power thereof, decreasing the turning-on power of the Ti source to be lower than the turning-off power thereof, or increasing the flow rate or temperature of the nitrogen gas upon introduction to be higher than upon termination of the introduction thereof.

In addition, a low friction coating apparatus according to the present invention may include a jig 300 having a substrate, a feeder 400 configured to introduce a nitrogen gas as an atmosphere gas, a Ti source 100 and a low friction metal source 200, and a controller 500 configured, during coating, to increase the turning-on power of the low friction metal source to be higher than the turning-off power thereof, decrease the turning-on power of the Ti source to be lower than the turning-off power thereof, or increase the flow rate or temperature of the nitrogen atmosphere gas when introduced to be higher than the flow rate or temperature of the nitrogen atmosphere gas when the introduced ceases.

FIG. 6 is an exemplary graph illustrating the effects of the low friction coating layer according to an embodiment of the present invention. As illustrated, when the turning-on power of each source is substantially the same as the turning-off power thereof, the low friction characteristics of the surface of a part may decrease over time, compared to the present invention. The lapse of the friction/wear testing period in a conventional product is accompanied by wear of the coating layer, undesirably increasing the coefficient of friction of the conventional coating layer. However, in the present invention, the coefficient of friction may be maintained as a lower coefficient for an extended testing period.

In the low friction coating layer having the above structure, the low friction coating method and the low friction coating apparatus according to the present invention, a decrease in low friction characteristics due to wear by use upon forming a coating layer without changes in process conditions as in conventional coating production may be prevented. Furthermore, the coating layer may be improved in regard to performance reliability due to substantially uniform quality at different depths thereof.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A low friction coating method using a plasma coating process, comprising:
increasing a turning-on power of a low friction metal source to be higher than a turning-off power of the low friction metal source, and
decreasing a turning-on power of a titanium (Ti) source to be lower than a turning-off power of the Ti source.

2. The method of claim 1, further comprising:
increasing a flow rate or temperature of a nitrogen atmosphere gas upon introduction to be higher than upon termination of the introduction thereof, to increase the uniform concentration of the low friction metal in a coating layer.

2. The method of claim 2, wherein the low friction metal is silver (Ag) or copper (Cu), and the coating layer is titanium silver nitride (TiAgN) or titanium copper nitride (TiCuN).

3. The method of claim 2, wherein the turning-on power of the low friction metal source is about 5˜10% higher than the turning-off power of the low friction metal source.

4. The method of claim 2, wherein the turning-on power of the Ti source is about 3˜7% lower than the turning-off power of the Ti source.

5. The method of claim 2, wherein the flow rate of the nitrogen atmosphere gas upon introduction is about 20˜50% higher than upon termination of the introduction thereof.

6. The method of claim 2, wherein the temperature of the nitrogen atmosphere gas upon introduction is about 15˜20% higher than upon termination of the introduction thereof.

7. A low friction coating method using a plasma coating process, comprising:
increasing a turning-on power of a low friction metal source to be higher than a turning-off power of the low friction metal source, and
increasing a flow rate or temperature of a nitrogen atmosphere gas upon introduction to be higher than upon termination of the introduction thereof, to increase the uniform concentration of the low friction metal in a coating layer.

8. The method of claim 7, further comprising:
decreasing a turning-on power of a titanium (Ti) source to be lower than a turning-off power of the Ti source.

9. A low friction coating layer, formed via a plasma coating process using a low friction metal source, a Ti source and a nitrogen gas, wherein uniform concentration of a low friction metal in the coating layer is increased by increasing turning-on power of the low friction metal source to be higher than turning-off power thereof, decreasing turning-on power of the Ti source to be lower than turning-off power thereof, or increasing a flow rate or temperature of a nitrogen atmosphere gas upon introduction to be higher than upon termination of the introduction thereof.

10. A low friction coating apparatus using a plasma coating process, comprising:
a jig having a substrate;
a feeder configured to introduce a nitrogen gas as an atmosphere gas;
a titanium (Ti) source;
a low friction metal source; and
a controller configured during coating to;
increase a turning-on power of the low friction metal source to be higher than turning-off power thereof;
decrease a turning-on power of the Ti source to be lower than turning-off power thereof;
or increase a flow rate or temperature of a nitrogen atmosphere gas upon introduction to be higher than upon termination of the introduction thereof.
